(19) United States
(12) Patent Application Publication
(10) Pub. No.: US 2008/0107811 A1
(43) Pub. Date: May 8, 2008

(54) Apparatus For Vacuum Deposition With A Recharging Reservoir And Corresponding Process For Vacuum Deposition

(75) Inventors: Jean-Louis Guyaux, Chilly Mazarin (FR); Franck Stemmelen, Jouy-Le-Moutier (FR); Pierre Bouchaib, Mantes La Ville (FR)

Correspondence Address: IP GROUP OF DLA PIPER US LLP, ONE LIBERTY PLACE, 1650 MARKET ST, SUITE 4900, PHILADELPHIA, PA, 19103, US

(73) Assignee: ADDON, Carrieres-sur-Seine (FR)

(21) Appl. No.: 11/792,554

(22) PCT Filed: Dec. 7, 2005
(86) PCT No.: PCT/FR05/03072

§ 371 Date: Jun. 25, 2007

(30) Foreign Application Priority Data
Dec. 7, 2004 (FR) 0413025

(51) Int. Cl. C23C 14/24; C23C 14/26; C23C 14/12

(52) U.S. Cl. 427/255.6; 118/726

(57) ABSTRACT

A vacuum deposition apparatus comprising an enclosure adapted to receive a substrate to be treated and placed under a vacuum; at least one injector that generates a molecular beam of vapor of an organic material the injector comprising a conduit located inside the enclosure and traversing an injection wall of the enclosure to form an outer nozzle adapted in such a manner as to be hermetically connected in a detachable manner to an organic material supply, wherein the supply is a bottle whose neck is adapted to be introduced into the nozzle; an outer heating apparatus located on both sides of an injection wall and surrounding the bottle; an inner heating apparatus surrounding the conduit; and a regulatable valve permitting regulation of conductance of the injector in the enclosure.

### RELATED APPLICATION

This is a §371 of International Application No. PCT/FR2005/003072, with an international filing date of Dec. 7, 2005 (WO 2006/061517 A1, published Jun. 15, 2006), which is based on French Patent Application No. 04/13025, filed Dec. 7, 2004.

### TECHNICAL FIELD

This disclosure relates to the area of vacuum deposition. It concerns more particularly the vacuum deposition of thin films of organic material, e.g., for the manufacture of electroluminescent diodes based on organic materials (OLED).

### BACKGROUND

The structure of an elementary cell of an OLED apparatus is constituted of a stack of very fine organic layers sandwiched between a transparent anode and a metallic cathode. The manufacture of these organic layers is carried out by evaporation of the material or materials constituting the layers and by vacuum deposition.

One of the problems posed by this manufacturing process is that of the introduction into an enclosure under a vacuum containing the substrate of the evaporated organic material to be treated.

A known apparatus used to implement this process is described in U.S. Pat. No. 4,553,022 and comprises a thermal effusion cell constituted of a crucible containing the organic material to be evaporated and a furnace that permits the heating of the crucible. This thermal effusion cell can be introduced into the enclosure. The material contained in the crucible is then heated to a given temperature at which the evaporated material escapes via the crucible orifice toward the surface of the substrate, where it is deposited to form a thin film. To interrupt the operation of the deposition of the thin film, a mask is interposed between the crucible and the substrate that forms an obstacle to the vapor flow. The material is then deposited on the surface of the mask or on the inner walls of the enclosure and can consequently no longer be used.

Moreover, the crucible heating furnace is located facing the substrate in the vacuum enclosure and the heat that it emits risks damaging the thin deposited film.

Finally, it is necessary to open the enclosure to recharge the crucible and conesquently expose the enclosure to the air again. It is necessary to do the same to interact with the furnace that is located in the enclosure.

There are patents in the technical area of molecular beam epitaxy (MBE) such as U.S. Pat. No. 5,080,870 or U.S. Pat. No. 5,156,815 that describe an apparatus in which the main enclosure containing the substrate communicates with a secondary enclosure adapted in such a manner as to receive a reservoir containing the material to be evaporated. An injection tube can be open or closed by a valve. The secondary enclosure and the reservoir are each provided with tight covers permitting a hermetic closure. The secondary enclosure and the main enclosure are connected by a tight flange. A heating apparatus surrounds the reservoir as well as the injection tube.

Such an apparatus allows the vapor flow to be controlled by the valve arranged between the reservoir and the main enclosure.

However, here too the reservoir can only be recharged after opening the tight cover of the secondary enclosure, which means that the unit of the secondary enclosure/main enclosure is exposed to the air.

It could therefore be advantageous to provide an apparatus and a process permitting the production of vapors under a vacuum of organic materials in which a product reservoir can be readily recharged.

### SUMMARY

We provide a vacuum deposition apparatus including an enclosure adapted to receive a substrate to be treated and placed under a vacuum; at least one injector that generates a molecular beam of vapor of an organic material, the injector including a conduit located inside the enclosure and traversing an injection wall of the enclosure to form an outer nozzle adapted in such a manner as to be hermetically connected in a detachable manner to an organic material supply, wherein the supply is a bottle whose neck is adapted to be introduced into the nozzle; an outer heating apparatus located on both sides of an injection wall and surrounding the bottle; an inner heating apparatus surrounding the conduit; and a regulatable valve permitting regulation of conductance of the injector in the enclosure.

We also provide a vacuum deposition process conducted with the apparatus, including a recharging step including closing the valve; detaching the bottle from the injector; recharging the reservoir; connecting another bottle to the injector; progressively opening the valve; heating the conduit; heating the valve; and heating the reservoir.

### BRIEF DESCRIPTION OF THE DRAWINGS

The apparatus will be better understood with the aid of the description of an representative apparatus given in the following purely explicative manner and making reference to the attached figures in which:

FIG. 1 is a schematic view of a vacuum deposition apparatus with a recharging reservoir;

FIG. 2 is a schematic view of alternate aspects of recharging reservoirs for the apparatus of FIG. 1; and

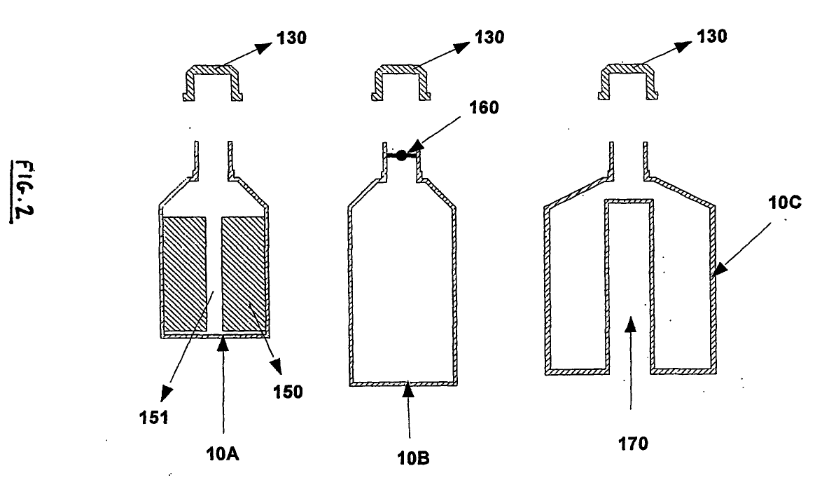

FIG. 3 is a schematic view illustrating the different recharging steps of a vacuum deposition process.

### DETAILED DESCRIPTION

We provide a vacuum deposition apparatus comprising an enclosure adapted to receive a substrate to be treated and placed under a vacuum and at least one injector for generating a molecular beam of vapor of an organic material, which injector comprises a conduit located inside the enclosure and traversing an injection wall of the enclosure to form an outer nozzle adapted in such a manner as to be hermetically connected in a detachable manner to a means for supplying organic material, characterized in that the supply means is a bottle whose neck is adapted in such a manner that it can be introduced into the nozzle and the deposition apparatus comprises an outer heating apparatus located on both sides of the injector wall and surrounding the bottle and an inner heating apparatus surrounding the conduit, and that a regulatable valve permits regulation of the conductance of the injector in the enclosure.

The apparatus permits recharging of organic materials carried out from the outside of the vacuum enclosure and the recharging operation does not require the vacuum enclosure to be exposed to the air. The capacity of organic materials can be adjusted to whatever the size of the chamber.

The conduit of this injector may be provided with a heating apparatus adapted in such a manner as to prevent the deposition of the organic material on this conduit.

The valve may be provided with a heating apparatus adapted in such a manner as to prevent deposition of the organic material on the valve.

The removable reservoir advantageously has the shape of a bottle with a cylindrical body and a neck whose end is adapted in such a manner as to be introduced into the outer end of the conduit of the injector.

The removable reservoir advantageously comprises a plurality of metallic blades inside its cylindrical body that extend radially between the wall of the reservoir and the central tube extending over the entire length of the cylindrical body.

Such an apparatus allows transmission of heat to the interior of the reservoir to be improved in such a manner as to avoid accumulation of the product in the central zone of the reservoir.

The removable reservoir may have a cylindrical body with an annular section.

In this way, a heating apparatus can be axially introduced through the bottom of the reservoir. This is another manner of avoiding accumulation of the product in the central zone of the reservoir.

The removable reservoir is advantageously provided with a valve at the level of its neck.

The conduit of the injector may be vertical and may traverse the bottom of the vacuum enclosure and the substrate may extend horizontally in an upper part of the enclosure.

The heating furnace advantageously heats the reservoir with a temperature gradient between the base and the neck of the reservoir, between the neck and the valve and between the valve and the inner mouth of the conduit.

We also provide a process of vacuum deposition using an apparatus such as defined above, characterized in that it comprises the recharging steps:

closing the valve;

detaching the reservoir from the injector;

recharging the reservoir;

connecting the reservoir to the injector;

progressively opening the valve;

heating the conduit;

heating the valve; and

heating the reservoir.

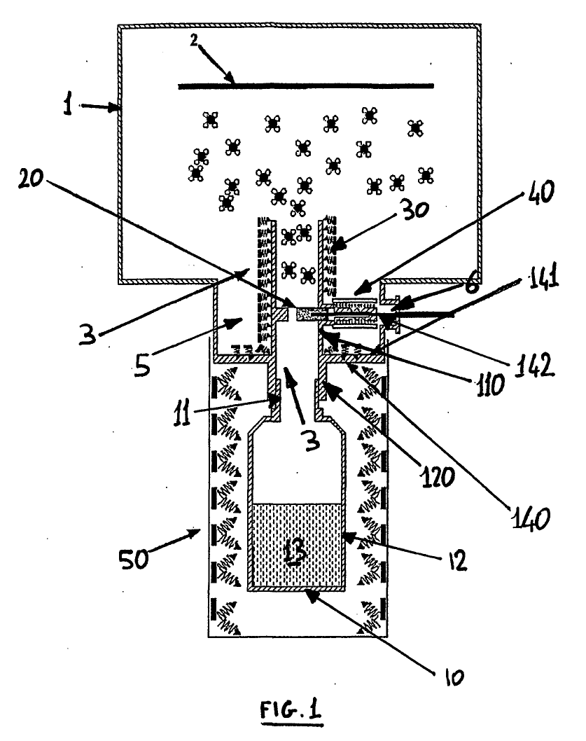

Turning now to the drawings, FIG. 1 schematically represents an apparatus for the vacuum deposition of thin films. It can concern the deposition of organic materials or of materials under a strong vapor pressure that will be designated in the following by the term of charge. Such an apparatus serves, e.g., for the manufacture of electroluminescent diodes based on organic materials (OLED). The charge is solid under normal conditions of temperature and pressure.

The apparatus comprises an enclosure 1 adapted to receive a substrate 2 extending horizontally in an upper part of enclosure 1. The bottom of the enclosure comprises an injection compartment 5 with a cylindrical form open at the top on the enclosure and closed at the bottom by wall 141.

An injection cell 3 is adapted to inject a charge into enclosure 1 in the form of a vapor beam extending substantially in the form of a cone whose dimensions are such that substrate 2 substantially forms the base of the cone.

Injection cell 3 comprises a cylindrical injector vertically traversing wall 141 of injection compartment 5. The injector can be mounted in a permanent manner on the enclosure or in a removable manner to permit its replacement by another injector, e.g., to modify the characteristics of the injection. The injector conduit comprises a main part 10 extending inside the enclosure and comprises a nozzle 120 extending outside of the enclosure.

Injector conduit 110 has a form adapted to the generation of a molecular beam with the desired form. The conduit can terminate in a mouth in the form of a truncated cone, of an extended diffuser of the knob type or of a gas burner or any type of known diffuser.

Outer nozzle 120 is adapted for receiving neck 11 of removable charge reservoir 10. Outer part 120 of the conduit forming a nozzle is designed to be a short as possible as a function of the hooking requirements of reservoir 10.

Valve 20 is arranged on inner part 110 of the injector. The valve is adapted in a closed position to hermetically close the conduit.

Valve 20 is slidingly mounted in a transversal housing in such a manner that it can move perpendicularly to the axis of the injector between the position of closing in which it totally plugs the conduit of the injector and between the position of opening. The valve is controlled by shaft 142 extending transversely in injection compartment 5 and can be controlled by a handle located outside of enclosure 1 and the passage of the enclosure is ensured through a tight apparatus 6.

Valve 20 permits the conductance of the injector to be regulated, that is, the delivery of molecules can be made to vary in a continuous manner. The valve is advantageously piloted by a motor acting on shaft 142. The motor can be controlled by a controller that adjusts the position of the valve using a signal coming from a measuring apparatus sensitive to the molecular flow (quartz balance) to maintain the molecular flow at a value predetermined by the operator. Piloting the valve motor permits the user to obtain molecular flow profiles as a function of the time predefined by programming the successive positions of the valve.

Removable charge reservoir 10 has on the whole the shape of a bottle with cylindrical body 12 and neck 11 whose extremity is adapted to be introduced into nozzle 120 of the injector. The neck is connected in a tight manner to the injector nozzle in such a manner that once the reservoir is installed, the injector conduit is isolated from the outer atmosphere.

The neck can advantageously be screwed into the injector conduit.

The tightness between the bottle neck and the injector is ensured by a metallic joint.

The reservoir is manufactured from a material that is chemically inert to the organic material and can tolerate temperatures between −50° C. and +600° C. without deforming or its qualities of tightness being affected. The reservoir 10 can be made of metal, graphite, glass, quartz, PBN, PG, alumina or several of these materials. The useful volume of the reservoir can advantageously be from 1 cm³ to several liters.

The inner surface of the reservoir has a very slight rugosity.

The shape of the reservoir is such that it has a maximal surface for the heating.

The reservoir advantageously has a diameter D >30 mm and the ratio of the height to the diameter is greater than two.

The reservoir can be equipped, in addition to a filling orifice, with one or several different entrances permitting, e.g., the introduction of an inert or reactive gas into the recharge and/or permitting the pumping of the inside of the recharge.

When the reservoir is detached from injector 100 and closed by plug 130 it is tight against the outside and can retain a vacuum on the order of 10e⁻⁸ torr without pumping for 1 week.

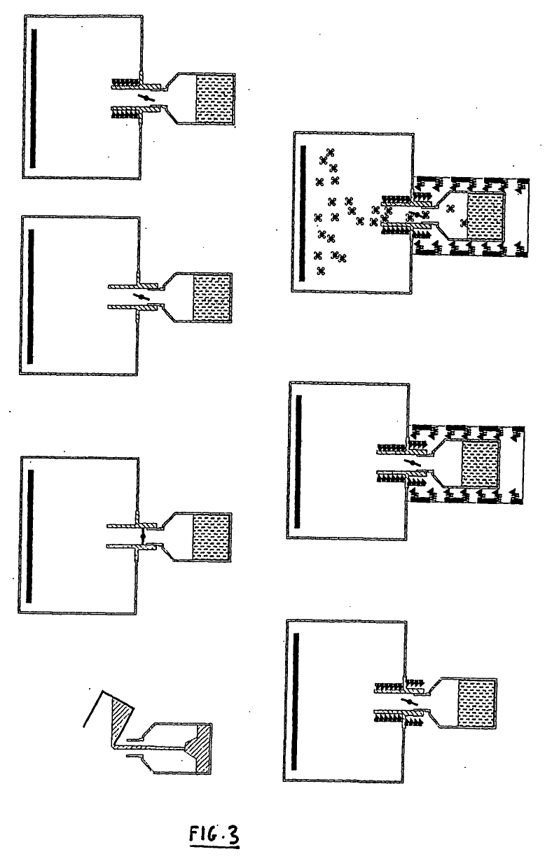

FIG. 3 represents alternate aspects of reservoir 10. The shape of the extremity of the neck is substantially identical so that each of the represented reservoirs can be installed on the nozzle of injector 3. Plug 130 permits the closing of the reservoir when it is not mounted on injector 3.

In a first alternate construction 10A, a plurality of metallic blades 150 extend radially between wall 152 of the reservoir and central tube 151 extending over the entire height of this cylindrical body.

This apparatus permits transmission of heat to the inside of the reservoir to be improved in such a manner as to avoid an accumulation of the product in the central zone of the reservoir.

In construction 10C, the reservoir has a cylindrical body with an annular section in such a manner that a housing open toward the bottom 170 extends along its axis. A heating apparatus can be axially introduced through the bottom to avoid an accumulation of the product in the central zone of the reservoir.

In construction 10B, a valve 160 is installed at the level of the reservoir neck.

Of course, the characteristics of these three constructions can be combined in one and the same reservoir.

A removable furnace 50 allows reservoir 10 to be heated. The furnace is constituted of a tank closed at the level of its lower part and open at the level of its upper part. The inside diameter of the furnace can receive bottle 10 and fits against outer wall 140 of injection compartment 5 in such a manner as to form a closed cavity enclosing the bottle. Heating elements integrated in the tank walls of furnace 50 are spaced in the tank in such a manner as to heat the walls of reservoir 10 and wall 140 of injection compartment 5. The heating elements are, e.g., lamps or heating resistors. Furnace 50 comprises a temperature measuring apparatus that allows the temperature of the reservoir to be measured (thermocouple or platinum probe). The furnace heating elements are supplied in wattage by an independent feed that can be regulated in its temperature by the temperature measuring apparatus.

Removable furnace 50 has the particular function of bringing the charge to the desired temperature for generating the molecular beam. The temperature is advantageously comprised between about 50 and about 600 degrees.

Heating system 50 is located entirely outside of enclosure 1 and is independent of the latter.

According to another aspect, the conduit of lower part 110 of the injector is heated with the aid of inner heating apparatus 30. A heating element, e.g., a heating cable, surrounds the outer surface of inner injector cylinder 110 and also extends (e.g., in a spiral) against the inner surface of lower wall 141 of injection compartment 5. In this manner, the injector is heated uniformly from its base to the level of the bulkhead up to its inner mouth. A temperature measuring means at the level of the injector extremity (thermocouple or platinum probe) allows the temperature to be measured at the level of the inner mouth of the injector. The injector heating element is supplied in wattage by an independent feed that can be regulated in its temperature by the temperature measuring apparatus.

According to another aspect, valve 20 is heated with the aid of a valve heating apparatus 40 located in injection compartment 5. A heating element, e.g., a heating cable, surrounds control shaft 142, and the heat is transmitted to the valve body by conduction. A temperature measuring apparatus is installed on the valve body. The valve heating element is supplied in wattage by an independent feed that can be regulated in its temperature by the temperature measuring apparatus.

Heating apparatus 30 heats the injector walls in such a manner that the charge is not deposited on these walls, and heating apparatus 40 heats the valve 30 in such a manner that the charge is not deposited on the valve. Heating apparatuses 30, 40 are independent from one another and from heating apparatus 50.

According to an alternative, the heating apparatuses also allow a cooling of the various injector elements.

According to another aspect, heating apparatuses 50, 40 and 30 respectively heat the reservoir, the valve and the injector in such a manner that there is a temperature gradient between the base and the reservoir neck, between the neck and the valve and between the valve and the inner mouth of the injector. In other words, the temperature at the base of the reservoir is lower than the temperature at the level of the neck, itself lower than that of the valve and itself lower than that of the inner mouth of the injector. The control of the gradient is ensured by independent feeds of the three heating means associated with temperature sensors. The heating elements in reservoir 50 are arranged so as to heat the bottom more than the top of the reservoir. Likewise, the spacing of the winding lengths of heating cable 30 is selected with a view to supply a division of power at the height of the injector ensuring this gradient. The fact that the heating of the reservoir allows outer surface 140 of the lower wall of injection compartment 5 to be heated from the outside and that the heating of the injector allows lower surface 141 of this wall to be heated from the inside allows the continuity of the temperature gradient of the injector conduit to be guaranteed between the outside and the inside.

FIG. 3 schematically represents several charge or recharge stages within the scope of a vacuum deposition process. These charge or recharge stages take place when enclosure 1 is under a vacuum and valve 20 is closing the injector orifice.

1-9. (canceled)

10. A vacuum deposition apparatus comprising:
an enclosure adapted to receive a substrate to be treated and placed under a vacuum;
at least one injector that generates a molecular beam of vapor of an organic material, the injector comprising a conduit located inside the enclosure and traversing an injection wall of the enclosure to form an outer nozzle adapted in such a manner as to be hermetically connected in a detachable manner to an organic material supply, wherein the supply is a bottle whose neck is adapted to be introduced into the nozzle;
an outer heating apparatus located on both sides of an injection wall and surrounding the bottle;
an inner heating apparatus surrounding the conduit; and
a regulatable valve permitting regulation of conductance of the injector in the enclosure.

11. The vacuum deposition apparatus according to claim 10, wherein the valve of the injector is provided with a heating apparatus adapted to prevent deposition of the organic material on the valve.

12. The vacuum deposition apparatus according to claim 10, further comprising a removable reservoir adapted to be filled with solid organic material, placed under a vacuum and closed by a plug to preserve a vacuum on the order of 10e⁻⁸ torr for one week.

13. The vacuum deposition apparatus according to claim 10, wherein the bottle comprises a plurality of metallic blades that extend radially between a wall of the reservoir and a central tube extending over the entire length of a cylindrical body of the bottle.

14. The vacuum deposition apparatus according to claim 10, wherein the bottle has a cylindrical body with an annular section.

15. The vacuum deposition apparatus according to claim 10, wherein the bottle is provided with a valve at its neck.

16. The vacuum deposition apparatus according to claim 10, wherein the conduit of the injector is vertical and traverses the bottom of the vacuum enclosure and the substrate extends horizontally in an upper part of the enclosure.

17. The vacuum deposition apparatus according to claim 10, wherein the heating furnace heats the bottle with a temperature gradient between a base and a neck of the bottle, between the neck and the valve and between the valve and an inner mouth of the injector.

18. A vacuum deposition process conducted with an apparatus according to claim 10, comprising a recharging step comprising:
closing the valve;
detaching the bottle from the injector;
recharging the reservoir;
connecting another bottle to the injector;
progressively opening the valve;
heating the conduit;
heating the valve; and
heating the reservoir.
